(19) United States
(12) Patent Application Publication
(10) Pub. No.: US 2025/0233371 A1
(43) Pub. Date: Jul. 17, 2025

(54) CONNECTOR ASSEMBLY

(71) Applicant: Molex, LLC, Lisle, IL (US)

(72) Inventor: Wei-Che Sun, New Taipei City (TW)

(21) Appl. No.: 19/011,683

(22) Filed: Jan. 7, 2025

(30) Foreign Application Priority Data
Jan. 16, 2024 (CN) 202410065866.4

(51) Int. Cl. H01R 13/6595; H01R 12/71

(52) U.S. Cl. CPC H01R 13/6595; H01R 12/716

(57) ABSTRACT

A connector assembly includes a guiding shield cage and a plurality of supporting seats. The guiding shield cage includes an outer shell and a plurality of supporting seat fixing portions which are formed to a bottom end of the outer shell, each supporting seat fixing portion includes a first engaging portion and a first supporting portion. The plurality of supporting seats are respectively assembled to the plurality of supporting seat fixing portions, each supporting seat includes a second engaging portion and a second supporting portion; the second engaging portion and the first engaging portion are engaged with and fixed to each other, the second supporting portion supports the first supporting portion relative to a direction that the outer shell is toward the down.

### TECHNICAL FIELD

The present disclosure relates to a connector assembly, and particularly relates to a connector assembly which allows a pluggable module to insert therein.

### BACKGROUND

Chinese patent document CN210092418U discloses a connector, in this technical solution, an outer shell is partitioned into four receiving cavities, which are linearly arranged, by third wall portions, and front ends of the receiving cavities are divided into upper inserting cavities and lower inserting cavities by using a partitioning piece assembly, a bottom portion of the outer shell is provided with elastic pins. Moreover, in this technical solution, the outer shell is fixed with a PCB only by that elastic pins are fixed in through holes of the PCB, retention force of the outer shell and resistance of the outer shell to insertion force are still strengthened in function and effect, specifically when the outer shell is uprightly provided on a circuit board, a height increases and a bottom face decreases, fixing function and strength would be more insufficient.

In addition, heat dissipating mechanism disclosed in this technical solution is mainly attained by heat dissipating holes of a first wall portion and a second wall portion of the outer shell, therefore, still mainly depends on wall portions of a periphery of the outer shell to perform heat dissipating, in connection with an internal heat dissipating mechanism, there still may be room for further improvement, for example, although this technical solution discloses that the partitioning piece assembly includes an upper partitioning piece and a lower partitioning piece which are spaced apart from each other by a gap, a front end of the upper partitioning piece and a front end of the lower partitioning piece attach together to form a closed state, heat dissipating air flow cannot enter into between the upper partitioning piece and the lower partitioning piece from the front end of the partitioning piece assembly, and the third wall portions which are used to perform partitioning also lack heat dissipating function.

### SUMMARY

Therefore, an object of the present disclosure is to provide a connector assembly which is capable of strengthening retention force and resistance to insertion force between an outer shell and a board in structure.

Accordingly, a connector assembly of the present disclosure comprises a guiding shield cage and a plurality of supporting seats. The guiding shield cage comprises an outer shell and a plurality of supporting seat fixing portions which are formed to a bottom end of the outer shell, each supporting seat fixing portion comprises a first engaging portion and a first supporting portion. The plurality of supporting seats are respectively assembled to the plurality of supporting seat fixing portions, each supporting seat comprises a second engaging portion and a second supporting portion; the second engaging portion and the first engaging portion are engaged with and fixed to each other, the second supporting portion supports the first supporting portion relative to a direction that the outer shell is toward the down.

In some embodiments, each supporting seat fixing portion comprises a bulging portion which bulges outwardly from an outer surface of the outer shell and a recessed portion which is recessed from an inner surface of the outer shell.

In some embodiments, the first engaging portion comprises a plurality of pin holes which penetrate the supporting seat fixing portion, the first supporting portion comprises a bottom edge of a lower end of the supporting seat fixing portion; the second supporting portion of each supporting seat comprises a supporting platform portion, the second engaging portion comprises a plurality of fixing pins; the plurality of fixing pins are respectively engaged to the plurality of pin holes of the supporting seat fixing portion, the supporting platform portion extends inwardly relative to the outer shell and supports the bottom edge of the lower end of the supporting seat fixing portion.

In some embodiments, each supporting seat fixing portion further comprises a bottom cutout, the bottom edge of each supporting seat fixing portion and a bottom edge of the outer shell therebetween form the bottom cutout which is recessed upwardly, the supporting platform portion extends inwardly into the bottom cutout relative to the outer shell and supports the bottom edge of the lower end of the supporting seat fixing portion.

In some embodiments, each supporting platform portion has an inner face which faces an interior of the outer shell, the inner face of the supporting platform portion is not beyond the inner surface of the outer shell, one ends of the plurality of fixing pins positioned in the outer shell are not beyond the inner surface of the outer shell.

In some embodiments, the connector assembly further comprises a board, each supporting seat further comprises a body, a fastener cooperating hole which is positioned to the body and erect brackets which are positioned to a bottom end of the body, the fastener cooperating hole allows a fastener to pass through so as to lock the supporting seat to the board, the erect brackets are supported to a surface of the board.

In some embodiments, the fastener cooperating hole is a screw hole, and the board is provided with a penetrating hole which allows the fastener to upwardly pass through the penetrating hole from the board and be locked to the fastener cooperating hole.

In some embodiments, the outer shell comprises two end walls which face each other in a longitudinal direction and two side walls which face each other in a transverse direction, the plurality of supporting seats are provided to the two end walls, and the two adjacent supporting seats on each end wall are spaced apart from each other by a width distance of at least one supporting seat, the supporting seats of one of the two end walls and the supporting seats of the other of the two end walls are staggered by a width distance of at least one supporting seat in the transverse direction.

In some embodiments, an end of each fixing pin positioned in the recessed portion forms a mushroom-like head to be riveted to the recessed portion.

In some embodiments, the connector assembly further comprises a board, the guiding shield cage is uprightly assembled to the board to extend up and down toward a height direction, and the guiding shield cage further comprises a longitudinal partitioning component and transverse partitioning components, the longitudinal partitioning component and the transverse partitioning components partition an internal space of the outer shell into a plurality of inserting passageways, each inserting passageway has a front inserting opening which is away from the board and a bottom opening which is adjacent to the board.

An object of the present disclosure is to provide a connector assembly which is capable of promoting heat dissipating effect of an outer shell.

A connector assembly of the present disclosure allows a pluggable module to insert therein, the connector assembly comprises a board and a guiding shield cage. The board is formed with a plurality of air flow through holes. The guiding shield cage is provided to the board and comprises an outer shell, a longitudinal partitioning component and transverse partitioning components. The outer shell comprises two end walls which face each other in a longitudinal direction and two side walls which face each other in a transverse direction, the longitudinal partitioning component extends along the longitudinal direction, is assembled to the two end walls, and comprises two longitudinal partitioning plates which are spaced apart from each other and an air flow passageway which is formed between the two longitudinal partitioning plates and is communicated with the plurality of air flow through holes; the transverse partitioning components each comprise two transverse partitioning plates which are spaced apart from each other and an air flow passageway which is formed between the two transverse partitioning plates and is communicated with the air flow through hole, the transverse partitioning component extends along transverse direction and is assembled on the longitudinal partitioning component and one of the two side walls of the outer shell, so that an internal space of the outer shell is partitioned into a plurality of inserting passageways, each inserting passageway extends along an inserting direction of the pluggable module and has a front inserting opening which is away from the board and a bottom opening which is adjacent to the board.

In some embodiments, the longitudinal partitioning component and the board therebetween form a bottom end air flowing gap; the transverse partitioning component and the board therebetween form a bottom end air flowing gap.

In some embodiments, a bottom end of the longitudinal partitioning component is provided with raising protrusions, is raised over the board by the raising protrusions, the longitudinal partitioning component and the board therebetween form the bottom end air flowing gap

In some embodiments, a bottom end of the outer shell and the board therebetween form bottom end air flowing gaps.

In some embodiments, the bottom end of the outer shell has retaining legs and raising protrusions, the retaining legs are used to be fixed to the board, are raised over the board by the raising protrusions, the outer shell and an upper surface of the board therebetween form the bottom end air flowing gaps.

In some embodiments, the longitudinal partitioning component comprises a pair of longitudinal partitioning plates which are spaced apart from each other and a front end plate which extends along the longitudinal direction from between front ends of the two longitudinal partitioning plates, the two longitudinal partitioning plates therebetween define the air flow passageway, the front end plate has a plurality of air flow holes which cover most of a front end opening of the air flow passageway.

In some embodiments, the longitudinal partitioning component further comprises a bottom supporting piece which is interposed between the two longitudinal partitioning plates, the bottom supporting piece is partially positioned to a bottom end opening of the air flow passageway.

In some embodiments, the bottom supporting piece bends and extends from a bottom edge of one of the two longitudinal partitioning plates toward the other of the two longitudinal partitioning plates and has a protruding piece used to snap to an inserting hole which is provided to the other of the two longitudinal partitioning plates.

In some embodiments, the front end plate extends from a front end edge of one of the two longitudinal partitioning plates toward the other of the two longitudinal partitioning plates, and the front end plate has a protruding piece which is used to snap to the other of the two longitudinal partitioning plates.

In some embodiments, the transverse partitioning component comprises a pair of transverse partitioning plates which are spaced apart from each other, the two transverse partitioning plates therebetween define the air flow passageway, each transverse partitioning plate has a bendable piece which is positioned to a front end of the transverse partitioning plate and is locally positioned in a front end opening of the air flow passageway, positions of the two bendable pieces of the two transverse partitioning plates are staggered with each other along the transverse direction, the two bendable piece s are locally positioned in the front end opening of the air flow passageway.

In some embodiments, the transverse partitioning component further comprises side supporting pieces which are interposed between the two transverse partitioning plates, the two transverse partitioning plates are therebetween provided with internal supporting pieces.

In some embodiments, some of the side supporting pieces and the two transverse partitioning plates are integrally connected.

One effect of the present disclosure lies in that, by provision of the supporting seat fixing portion and the supporting seat, it may attain to strengthen retention force of the outer shell and resistance of the outer shell to insertion force in structure, and the supporting seat also does not affect that the pluggable module inserts into the inserting passageway, so the object of the present disclosure can be indeed attained

Another effect of the present disclosure lies in that, by formation of the air flow through hole of the board and the inserting passageway communicated with the air flow through hole, heat dissipating effect of the outer shell is efficiently promoted, furthermore, using the air flow passageways of the longitudinal partitioning component and the transverse partitioning component, and provision of the air flow holes of the longitudinal partitioning component, the front end opening of the transverse partitioning component and the bottom end air flowing gaps, it allows air flow to flow through the longitudinal partitioning component and the transverse partitioning component, it also make the longitudinal partitioning component and the transverse partitioning component have heat dissipating effect.

### BRIEF DESCRIPTION OF THE DRAWINGS

Other features and effects of the present disclosure will be apparent from embodiments with reference to the drawings, in which:

FIG. 1 is a perspective assembled view of an embodiment of a connector assembly of the present disclosure illustrating the connector assembly which allows a pluggable module to insert therein;

FIG. 2 is a perspective exploded view illustrating a structure of a board and a guiding shield cage of the embodiment;

FIG. 3 is a perspective view illustrating a structure of a first half shell of an outer shell and assembled positions of supporting seats of the embodiment;

FIG. 4 is a partial perspective view illustrating a structure of a second half shell of the outer shell of the embodiment;

FIG. 5 is a perspective exploded view illustrating a structure of a longitudinal partitioning component of the guiding shield cage of the embodiment;

FIG. 6 is a partially enlarged view of a part indicated by A of FIG. 5 illustrating a structure of a front end plate of the longitudinal partitioning component of the embodiment;

FIG. 7 is a partial perspective view illustrating structures of bottom supporting pieces of the longitudinal partitioning component of the embodiment;

FIG. 8A and FIG. 8B are perspective views from different angles illustrating that a transverse partitioning component of the embodiment includes two transverse partitioning plates;

FIG. 9 is a bottom perspective view illustrating bottom end openings of the longitudinal partitioning component and the transverse partitioning plates of the guiding shield cage;

FIG. 10 is a partial perspective view illustrating an assembled state of the longitudinal partitioning component and the transverse partitioning plates of the guiding shield cage;

FIG. 11 is a perspective view illustrating an internal structure of the embodiment;

FIG. 12 is a partially enlarged view of a part indicated by C of FIG. 11 illustrating bottom end air flowing gaps of end walls, the longitudinal partitioning component and the transverse partitioning components of the guiding shield cage;

FIG. 13 is a partially enlarged view of a part indicated by B of FIG. 3 illustrating structures of supporting seat fixing portions and the supporting seats of the embodiment; and

FIG. 14 is a perspective view from another angle relative to FIG. 13 illustrating an assembling relationship of the supporting seat fixing portions and the supporting seats of the embodiment.

### DETAILED DESCRIPTION

Before the present disclosure is described in detail, it is noted that the similar elements are indicated by the same reference numerals in the following described content.

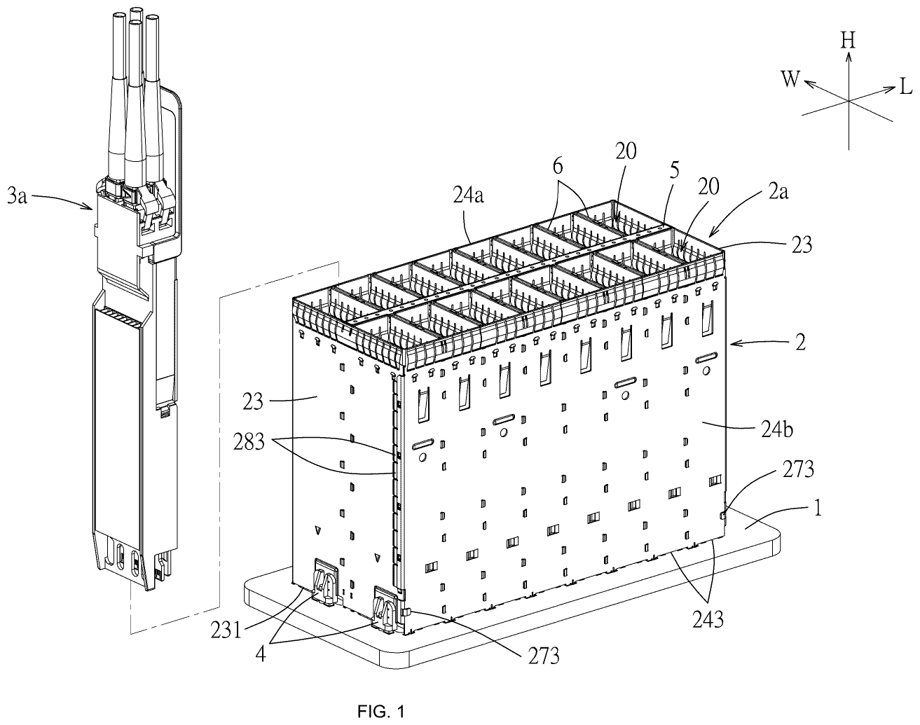

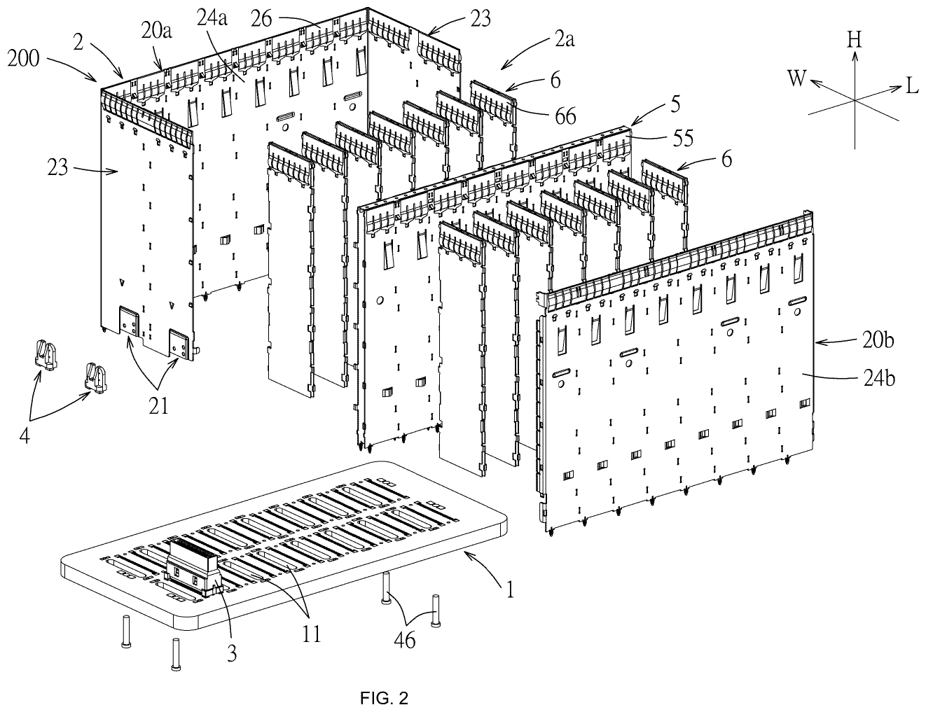

Referring to FIG. 1 to FIG. 5, an embodiment of a connector assembly of the present disclosure includes a board 1, a guiding shield cage 2a, a plurality of receptacles 3 (FIG. 2 only illustrates one receptacle 3) and a plurality of supporting seats 4. The guiding shield cage 2a is assembled to the board 1 uprightly relative to the board 1, and extends up and down toward a height direction H relative to the board 1, the plurality of receptacles 3 are provided on the board 1 to allow a pluggable module 3a to insert therein, and in the following embodiments, a front end is an end of the guiding shield cage 2a which is toward the up and is away from the board 1 in the figures, a bottom end is an end of the guiding shield cage 2a which is toward the down and is close to the board 1. The plurality of supporting seats 4 are assembled to a bottom portion of the guiding shield cage 2a, and are used to fix and support the guiding shield cage 2a on the board 1. Here, the present disclosure may efficiently increase heat dissipating efficacy by a heat dissipating mechanism formed between the guiding shield cage 2a and the board 1, and provision of the plurality of supporting seats 4 may provide retention force of the guiding shield cage 2a and resistance of the guiding shield cage 2a to insertion force in structure, which will be described in detail one by one below.

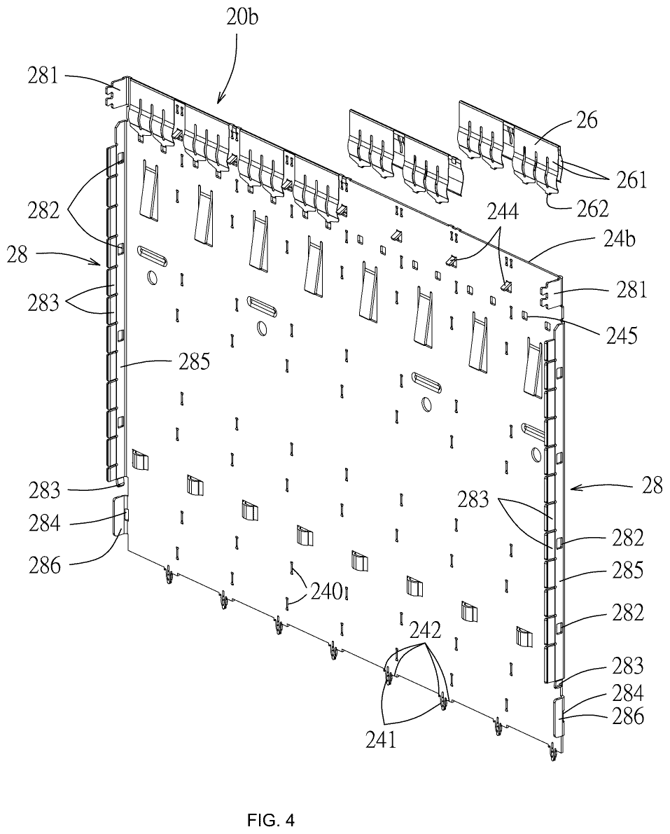

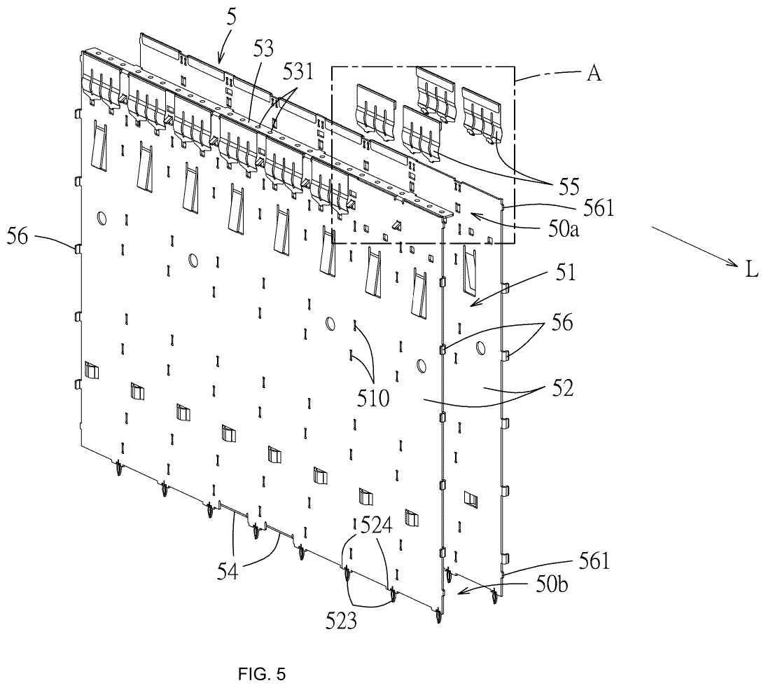

The guiding shield cage 2a includes an outer shell 2, a longitudinal partitioning component 5, a plurality of transverse partitioning components 6, and a plurality of inserting passageways 20. The longitudinal partitioning component 5 and the plurality of transverse partitioning components 6 cooperate with each other to partition an internal space of the outer shell 2 into the plurality of inserting passageways 20. A front end of the outer shell 2, a front end of the longitudinal partitioning component 5 and a front end of the transverse partitioning component 6 are provided with ground elastic pieces 26, 55, 66 respectively, a bottom end of the outer shell 2 and a bottom end of the longitudinal partitioning component 5 are provided with retaining legs 241, 523 (see FIG. 4 and FIG. 5) and raising protrusions 242, 524 respectively, the retaining legs 241, 523 each specifically may be for example pressing fit leg in form of eye of needle (EON). In addition, the guiding shield cage 2a further includes a plurality of supporting seat fixing portions 21 which are formed to the bottom end of the outer shell 2. The outer shell 2 includes two end walls 23 which face each other in a longitudinal direction L and two side walls 24a, 24b which face each other in a transverse direction W, the two end walls 23 and the two side walls 24a, 24b are connected with each other to form a box-like structure. In the present embodiment, the outer shell 2 includes a first half shell 20a and second half shell 20b which are assembled with each other, where the first half shell 20a includes one side wall 24a and the two end walls 23 which are integrally constructed, the second half shell 20b includes the other side wall 24b. The first half shell 20a is provided with first engaging portions 27, the second half shell 20b is provided with second engaging portions 28, the first half shell 20a and the second half shell 20b are assembled with each other by that the first engaging portions 27 and the second engaging portions 28 engage with each other. Here, the first engaging portions 27 are respectively provided at side edges of the two end walls 23 opposite to the side wall 24a connected with the two end walls 23, and each first engaging portion 27 includes a dovetail snapping groove 271, a plurality of latching protrusions 272 and a catch extending piece 273, each dovetail snapping groove 271 is formed to be recessed from an upper end of the side edge of the end wall 23, the plurality of latching protrusions 272 are spaced apart from each other up and down and are formed to be bulged from an outer surface of the end wall 23, each catch extending piece 273 is formed to extend out from the side edge of the end wall 23 close to a lower end of the side edge of the end wall 23. The second engaging portions 28 are respectively provided at two side edges of the side wall 24b, and each second engaging portion 28 includes a dovetail protruding piece 281, a plurality of latching holes 282, a plurality of elastic clipping pieces 283 and a catching hole 284, here, each dovetail protruding piece 281 is formed to protrude from an upper end of the side edge of the side wall 24b and is used to snap into the dovetail snapping groove 271 of the end wall 23, the plurality of latching holes 282 are arranged to be spaced apart from each other up and down and are provided on an extending wall 285 which bends and extends out from the side edge of the side wall 24b, and are used to allow the plurality of latching protrusions 272 to enter therein and latch therewith respectively, the elastic clipping piece 283 extends out from the extending wall 285, and is used to abut against the outer surface of the end wall 23 when the plurality of latching protrusion 272 latch to the plurality of latching holes 282 respectively, the catching hole 284 is provided on an extending piece 286 which bends and extends out from the side edge of the side wall 24b at the lower end of the side edge of the side wall 24b, the catching hole 284 allows the catch extending piece 273 to pass through and bend and be fixed to the side wall 24b.

The bottom end of the outer shell 2 and the board 1 are therebetween formed with bottom end air flowing gaps 231, 243. In the present embodiment, bottom ends of the two side walls 24a, 24b are constructed with a plurality of retaining legs 241 and a plurality of raising protrusions 242, the retaining legs 241 extend and protrude downwardly from the bottom end of each side wall 24a, 24b and are spaced apart from each other, two sides of each retaining leg 241 each are distributed with one raising protrusion 242, the retaining leg 241 downwardly extends beyond the raising protrusion 242, the retaining leg 241 is used to insert into and be fixed to a hole or a conductive hole of the board 1, and is raised over an upper surface of the board 1 by the raising protrusions 242, so that the bottom ends of the side walls 24a, 24b and the upper surface of the board 1 therebetween form the bottom end air flowing gaps 243. Bottom ends of the two end walls 23 of the outer shell 2 in the embodiment are away from the upper surface of the board 1 by a certain distance to constitute the bottom end air flowing gaps 231, but in a varied implementing manner, the bottom ends of the two end walls 23 also may be added with the retaining legs and the raising protrusions. The aforementioned ground elastic pieces 26 are respectively provided to front ends of the side walls 24a, 24b and the end walls 23 of the outer shell 2, each ground elastic piece 26 has a plurality of elastic fingers 261 which are respectively at two sides of the ground elastic piece 26 and hooks 262 which each are connected to bottom ends of the elastic fingers 261 at one same side of the ground elastic piece 26, the elastic finger 261 which is positioned at an inner side of each ground elastic piece 26 extends into the corresponding inserting passageway 20 and is used to contact the pluggable module 3a, the elastic finger 261 which is positioned at an outer side of the elastic finger 261 is used to contact for example a frame opening of a panel, the hook 262 are used to hook with corresponding hooking holes 245, 232 of the side walls 24a, 24b and the end walls 23.

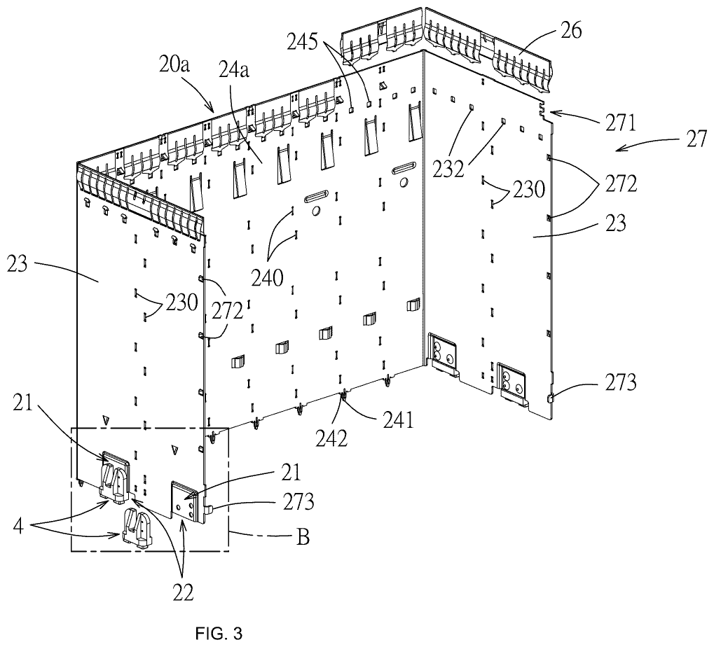

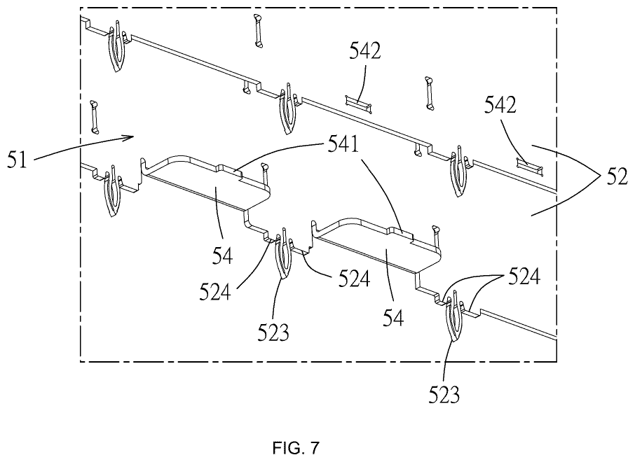

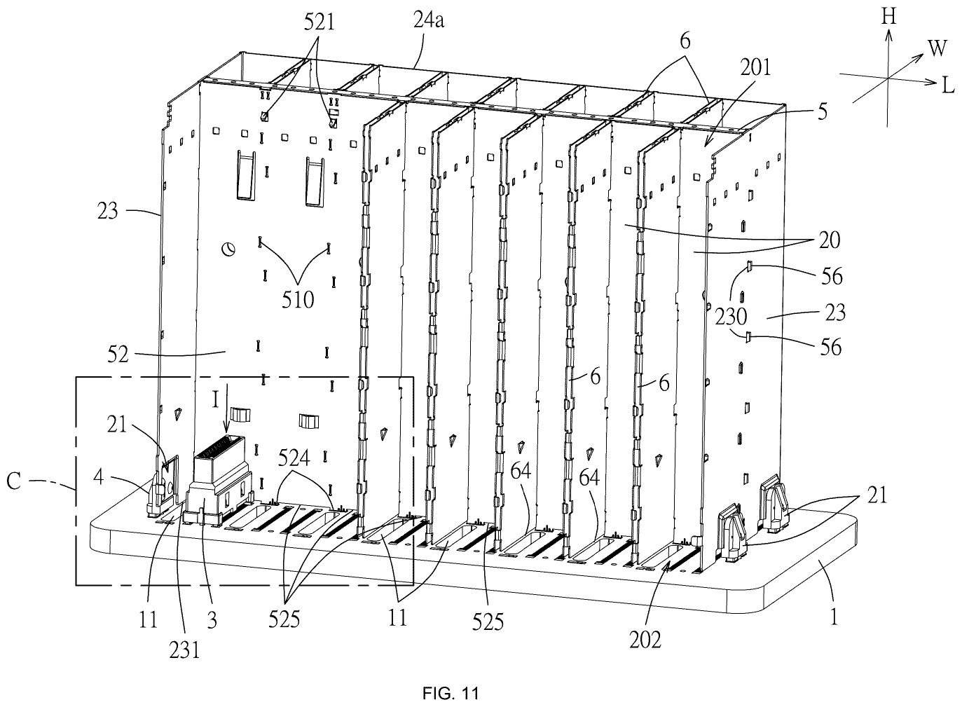

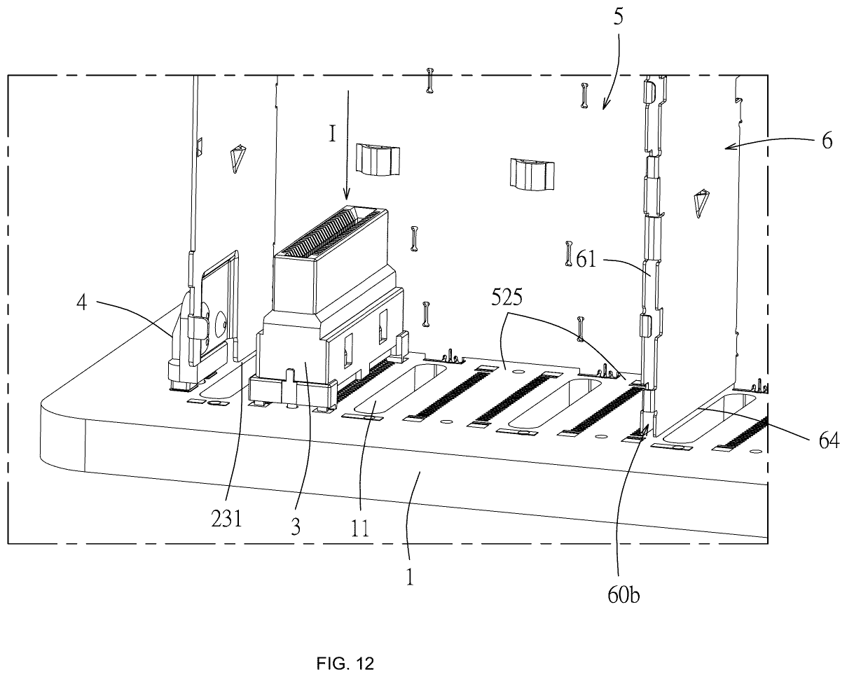

Referring to FIG. 1, FIG. 5 to FIG. 7, FIG. 11 and FIG. 12, the longitudinal partitioning component 5 extends along the longitudinal direction L and is assembled on the two end walls 23. the longitudinal partitioning component 5 includes two longitudinal partitioning plates 52 which are spaced apart from each other and an air flow passageway 51 which is formed between the two longitudinal partitioning plates 52, front ends of the two longitudinal partitioning plates 52 therebetween define a front end opening 50a (see FIG. 5) which is communicated with the air flow passageway 51, bottom ends of the two longitudinal partitioning plates 52 therebetween define a bottom end opening 50b (see FIG. 5) which is communicated with the air flow passageway 51. Moreover, the longitudinal partitioning component 5 further includes a front end plate 53 which extends along the longitudinal direction L and is provided between the front ends of the two longitudinal partitioning plates 52, at least one bottom supporting piece 54 and a plurality of assembling pieces 56, 561. The front end plate 53 may bend and extend from a front end edge of one of the two longitudinal partitioning plates 52 toward the other of the two longitudinal partitioning plates 52 and may be formed with a plurality of protruding pieces 532 which are spaced apart from each other and are used to snap to (interfere with) notches 533 which is provided to a front end edge of the other of the two longitudinal partitioning plates 52, and the front end plate 53 is provided with a plurality of air flow holes 531 which are communicated with the air flow passageway 51, the front end plate 53 may cover most of the front end opening 50a of the air flow passageway 51, but may be communicated with the air flow passageway 51 via the plurality of air flow holes 531. The bottom supporting piece 54 bends and extends from a bottom edge from one of the two longitudinal partitioning plates 52 toward the other of the two longitudinal partitioning plates 52 and snaps to the other of the two longitudinal partitioning plates 52, the bottom supporting piece 54 only is partially positioned to the bottom end opening 50b of the air flow passageway 51, in the present embodiment, the bottom supporting piece 54 has a protruding piece 541 which is used to snap to (interfere with) the other of the two longitudinal partitioning plates 52, the other of the two longitudinal partitioning plates 52 is provided with an inserting hole 542 which allows the protruding piece 541 to insert therein and interfere therewith, by provision of the front end plate 53 and the bottom supporting piece 54, a distance between the two longitudinal partitioning plates 52 may be maintained to constitute the air flow passageway 51. The plurality of assembling pieces 56, 561 are formed to two side edges of the two longitudinal partitioning plates 52, the assembling piece 56 is used to pass through a hole 230 (see FIG. 3) provided on the end wall 23 and then bend and be fixed on the end wall 23, so as to be engaged with the end wall 23 of the outer shell 2. Some of the plurality of assembling pieces 56,561 as the assembling pieces 561 which are positioned to upper ends and lower ends of the two side edges of the two longitudinal partitioning plates 52 may only snap into the holes 230 of the end walls 23 and do not need to bend, so as to provide positioning function.

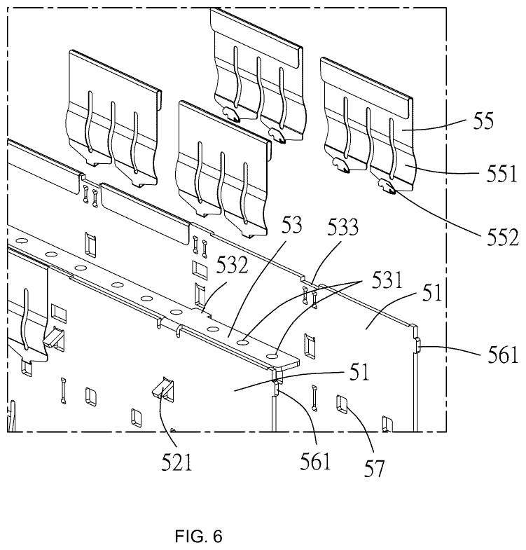

In the retaining legs 523 and the raising protrusions 524 which are provided to the bottom end of the longitudinal partitioning component 5, the retaining legs 523 are spaced apart from each other and extend and protrude downwardly from the bottom end of each longitudinal partitioning plate 52, two sides of each retaining leg 523 each are distributed with one raising protrusion 524, the retaining leg 523 downwardly extends beyond the raising protrusion 524, the retaining leg 523 is used to insert into and be fixed to the hole or the conductive hole of the board 1, and is raised over the upper surface of the board 1 by the raising protrusions 524, so that the bottom end of the longitudinal partitioning component 5 and the upper surface of the board 1 therebetween form bottom end air flowing gaps 525 (see FIG. 12). The aforementioned ground elastic pieces 55 are respectively provided to the front end of each longitudinal partitioning plate 52, each ground elastic piece 55 has a plurality of elastic fingers 551 which are positioned to a single side of the longitudinal partitioning plate 52 and are positioned to an outer side of the longitudinal partitioning plate 52 and hooks 552 which each are connected to bottom ends of the elastic fingers 551, the elastic finger 551 is used to extend into the inserting passageway 20, the hook 552 is used to hook with a corresponding hooking hole 57 (see FIG. 6) of the longitudinal partitioning plate 52.

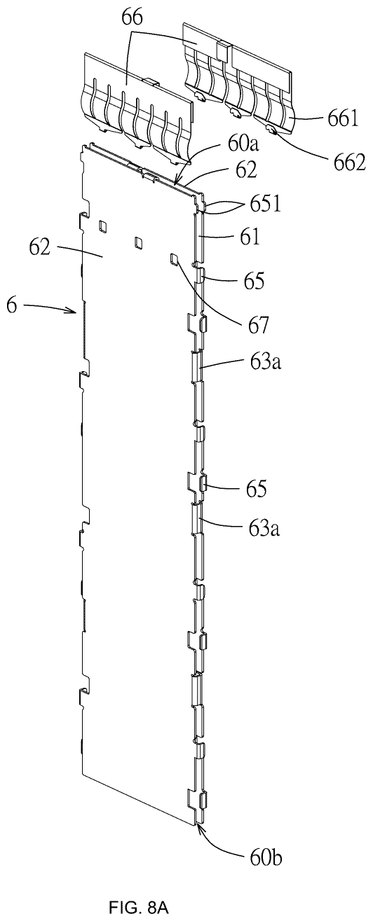

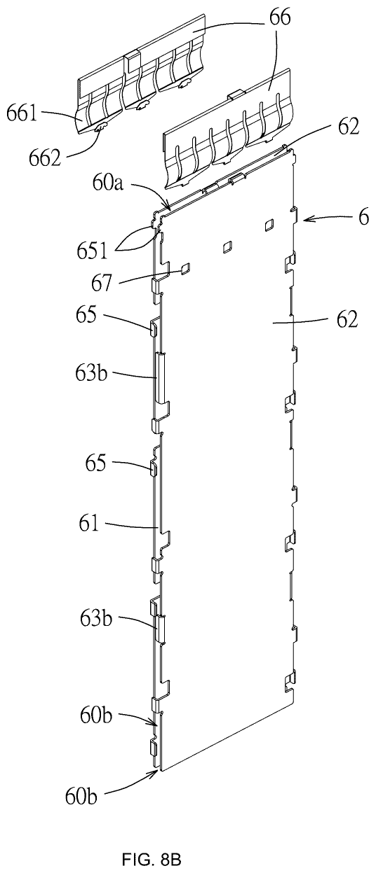

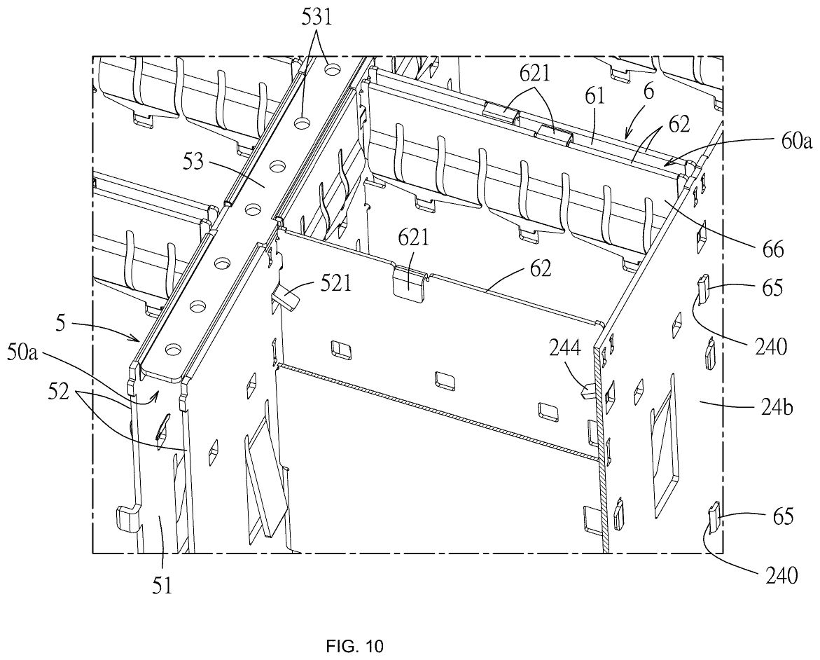

Referring to FIG. 1, FIG. 8A and FIG. 8B to FIG. 12, each transverse partitioning component 6 includes two transverse partitioning plates 62 which are spaced apart from each other and an air flow passageway 61 which is formed between the two transverse partitioning plates 62. The plurality of transverse partitioning components 6 are spaced apart from each other along the longitudinal direction L and are respectively assembled and provided between two sides of the longitudinal partitioning component 5 and the two side walls 24a, 24b of the outer shell 2 in the transverse direction W, to partition the internal space of the outer shell 2 into the plurality of inserting passageways 20, bottom ends of the two transverse partitioning plates 62 of each transverse partitioning component 6 are away from the upper surface of the board 1 by a certain distance, so that a bottom end of the transverse partitioning component 6 and the board 1 therebetween form a bottom end air flowing gap 64 (see FIG. 12). In a varied implementing manner, the bottom ends of the two transverse partitioning plates 62 of each transverse partitioning component 6 also may be added with retaining legs and raising protrusions. A bottom end of each inserting passageway 20 covers the receptacle 3 which is positioned on the board 1, each inserting passageway 20 extends along an inserting direction I of the height direction H, is upright relative to the board 1 and has a front inserting opening 201 which is away from the board 1 and the receptacle 3 and a bottom opening 202 which is adjacent to the board 1. In the present embodiment, each transverse partitioning component 6 further includes a plurality of side supporting pieces 63a, 63b which are interposed between the two transverse partitioning plates 62, and a plurality of assembling pieces 65, and the front end of each transverse partitioning component 6 between the two transverse partitioning plates 62 defines a front end opening 60a which is communicated with the air flow passageway 61, and the bottom end of each transverse partitioning component 6 between the two transverse partitioning plates 62 defines a bottom end opening 60b which is communicated with the air flow passageway 61. The plurality of side supporting pieces 63a, 63b may be formed to bend and extend from two side edges of one of the two transverse partitioning plates 62 toward the other of the two transverse partitioning plates 62, are used to maintain a distance between the two transverse partitioning plates 62 (i.e., maintain the air flow passageway 61), and in the present embodiment, the side supporting piece 63a which is positioned between the same one side edges of the two transverse partitioning plates 62 is integrally constructed and bends and connects the two transverse partitioning plates 62, and the side supporting piece 63b which is positioned to the other side edges of the two transverse partitioning plates 62 bends and extend integrally from one of the two transverse partitioning plates 62 and abuts against the other of the two transverse partitioning plates 62. The plurality of assembling pieces 65 are formed to the two side edges of the two transverse partitioning plates 62, the assembling pieces 65 which are positioned to each transverse partitioning plate 62 are used to pass through holes 510, 240 (see FIG. 10, FIG. 11) which are provided to the two longitudinal partitioning plates 52 of the longitudinal partitioning component 5 and the side walls 24a, 24b of the outer shell 2 and then bend and be fixed to the two longitudinal partitioning plates 52 of the longitudinal partitioning component 5 and the side walls 24a, 24b of the outer shell 2, and make the bottom ends of the two transverse partitioning plates 62 spaced apart from above the board 1 to form the bottom end air flowing gap 64. In the present embodiment, in combination with referring to FIG. 10, in order to assure that the plurality of transverse partitioning components 6 may stably be provided between the longitudinal partitioning component 5 and the side walls 24a, 24b of the outer shell 2, inner walls of the two transverse partitioning plates 62 of each transverse partitioning component 6 which face each other therebetween contain internal supporting pieces 521, 244, in the present embodiment, the two internal supporting pieces 521, 244 are respectively formed on each longitudinal partitioning plate 52 and the side wall 24a, 24b of the outer shell 2, the two internal supporting pieces 521, 244 specifically may be respectively formed to be locally stamped and obliquely bent from the longitudinal partitioning plate 52 and the side wall 24a, 24b of the outer shell 2, the two internal supporting pieces 521, 244 face each other, correspond to each other in position, and extend into between the two transverse partitioning plates 62 from two sides of the transverse partitioning component 6, so that the two internal supporting pieces 521, 244 are supported between the two transverse partitioning plates 62 of the transverse partitioning component 6. In addition, in the present embodiment, each transverse partitioning plate 62 of each transverse partitioning component 6 has a bendable piece 621 which is positioned to a front end of the transverse partitioning plate 62, bends toward an interior of the air flow passageway 61 and extends downwardly, the bendable pieces 621 at the front ends of the two transverse partitioning plates 62 of each transverse partitioning component 6 are staggered with each other along the transverse direction W and are locally positioned in the front end opening 60a of the air flow passageway 61, by formation of the two bendable pieces 621, it also may help to maintain the air flow passageway 61 between the two transverse partitioning plates 62, and, also may prevent the pluggable module 3a from being wrongly inserted into the air flow passageway 61. The aforementioned ground elastic pieces 66 each are provided to the front end of each transverse partitioning plate 62, each ground elastic piece 66 has a plurality of elastic fingers 661 which are positioned to a single side of the ground elastic piece 66 and are positioned to an outer side of the transverse partitioning plate 62 and hooks 662 which each are connected to bottom ends of the elastic fingers 661, the elastic finger 661 is used to extend into the inserting passageway 20, the hook 662 is used to hook with a corresponding hooking hole 67 of the transverse partitioning plate 62.

The aforementioned ground elastic pieces 26, 55, 66 are respectively provided at an inner side and an outer side of the front end of the end wall 23 of the outer shell 2, an inner side and an outer side of the front end of the side wall 24a, 24b of the outer shell 2, an outer side of the front end of the longitudinal partitioning plate 52 and an outer side of the front end of transverse partitioning plate 62, and are positioned to a position of the front inserting opening 201 of each inserting passageway 20, a periphery of the front inserting opening 201 of each inserting passageway 20 is basically distributed with the ground elastic pieces 26, 55, 66.

In the present embodiment, the board 1 is formed with a plurality of air flow through holes 11 which penetrate the board 1, each receptacle 3 is alongside provided with one air flow through hole 11, so that the bottom end of each inserting passageway 20 correspondingly has one receptacle 3 and one air flow through hole 11 therein, which thus may make each inserting passageway 20 have one corresponding air flow through hole 11 to be communicated therewith, assist in helping the inserting passageway 20 to dissipate heat.

As described above, in the present disclosure, by provision of the longitudinal partitioning component 5 and the transverse partitioning component 6, and the longitudinal partitioning component 5 and the transverse partitioning component 6 are formed with the air flow passageways 51, 61, and the air flow passageways 51, 61 are formed with the front end openings 50a, 60a and the bottom end openings 50b, 60b, further cooperating with the bottom end air flowing gaps 525, 64 between the bottom ends of the longitudinal partitioning component 5 and the transverse partitioning component 6 and the board 1, external cool air may enter into the interior of the longitudinal partitioning component 5 and the interior of the transverse partitioning component 6 respectively via the front end openings 50a, 60a, and then perform heat exchange with hot air inside the guiding shield cage 2a, next downwardly dissipate out via the bottom end openings 50b, 60b of the longitudinal partitioning component 5 and the transverse partitioning component 6, the bottom end air flowing gaps 525, 64 and the air flow through hole 11 of the board 1, and a part of heated air also may dissipate out via the air flowing gap 243 at the bottom end of the outer shell 2, so heat dissipating effect of the entire guiding shield cage 2a is promoted.

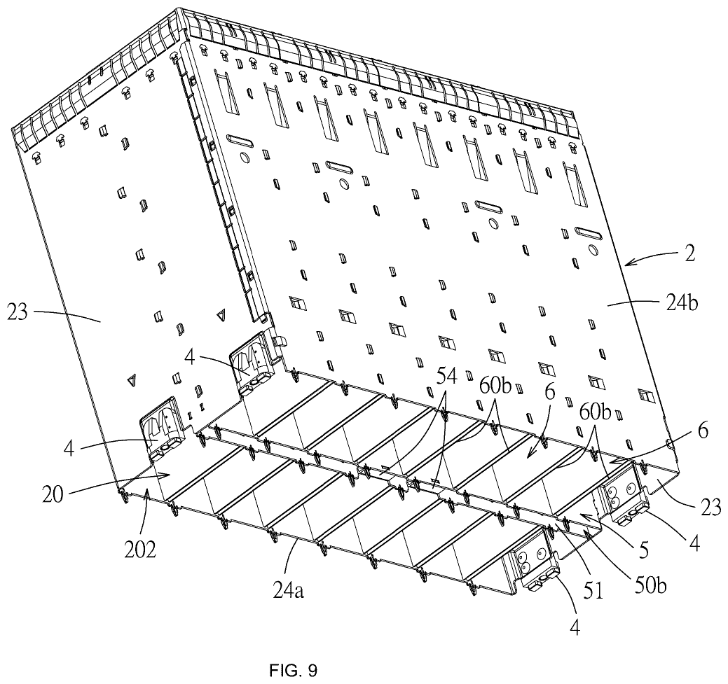

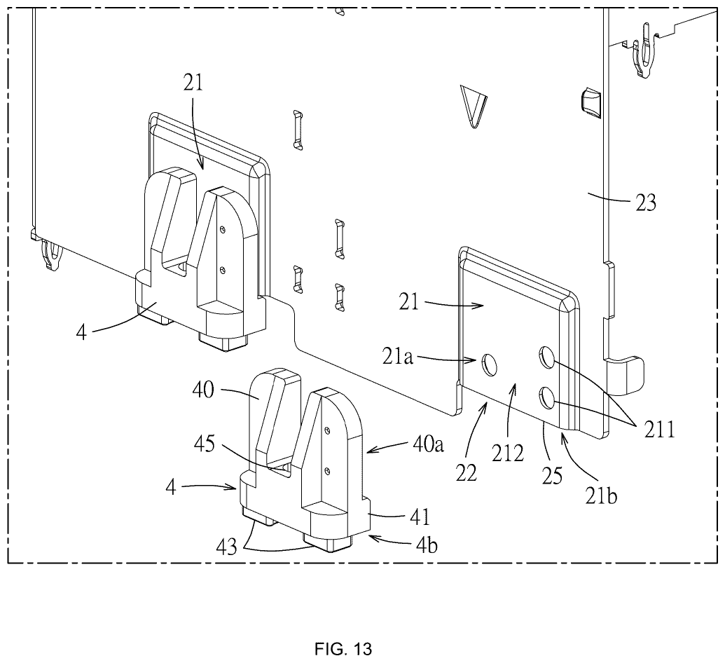

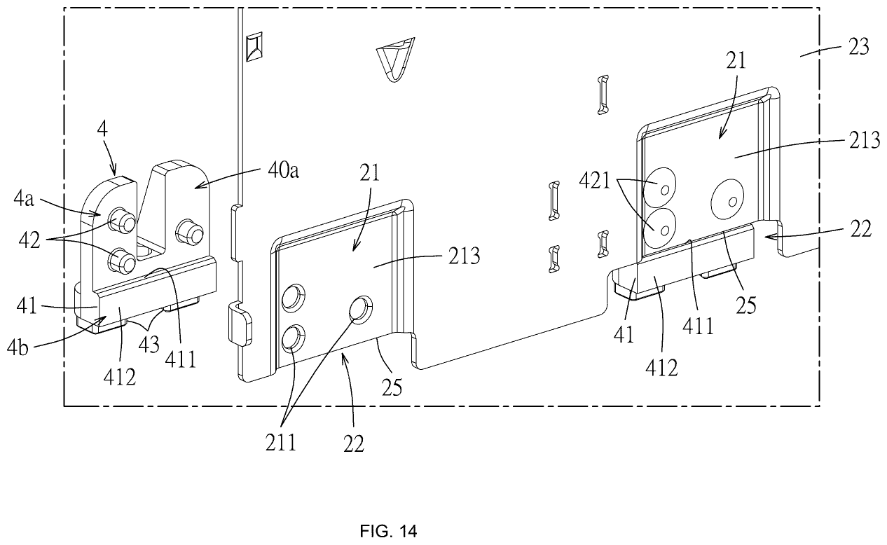

Referring to FIG. 9 and FIG. 11 to FIG. 14, the plurality of supporting seat fixing portions 21 are formed to lower ends of the two end walls 23 of the outer shell 2, each supporting seat fixing portion 21 includes a first engaging portion 21a and a first supporting portion 21b; the first engaging portion 21a includes a plurality of pin holes 211 which penetrate the supporting seat fixing portion 21. Each supporting seat fixing portion 21 includes a bulging portion 212 which bulges outwardly from an outer surface of the outer shell 2 and a recessed portion 213 which is recessed from an inner surface of the outer shell 2, in the present embodiment, the supporting seat fixing portion 21 is that a local region of the end wall 23 is stamped to make the outer surface of the end wall 23 bulged and make an inner surface of the end wall 23 recessed to form the bulging portion 212 and the recessed portion 213, the plurality of pin holes 211 are positioned in the region which is stamped and penetrate the bulging portion 212 and the recessed portion 213. The first supporting portion 21b includes a bottom edge 25 of a lower end of the supporting seat fixing portion 21, each supporting seat fixing portion 21 further includes a bottom cutout 22, the bottom edge 25 of each supporting seat fixing portion 21 and a bottom edge of the end wall 23 of the outer shell 2 therebetween form the bottom cutout 22 which is recessed upwardly.

Each supporting seat 4 is assembled to each supporting seat fixing portion 21. Each supporting seat 4 includes a second engaging portion 4a and a second supporting portion 4b, the second engaging portion 4a and the first engaging portion 21a cooperate with each other to be assembled, engaged and fixed together, the second supporting portion 4b supports the first supporting portion 21b relative to a direction that the outer shell 2 is toward the down; the second supporting portion 4b of each supporting seat 4 includes a supporting platform portion 41, the second engaging portion 4a includes a plurality of fixing pins 42; the supporting platform portion 41 inwardly extends into the bottom cutout 22 relative to the outer shell 2 and supports the bottom edge 25 of the supporting seat fixing portion 21, the fixing pin 42 is engaged to the pin hole 211 of the supporting seat fixing portion 21. Each supporting seat 4 of the present embodiment further includes a body 40 which is substantially concave shape, a fastener cooperating hole 45 which penetrates the body 40 in the height direction H, and two erect brackets 43 which protrude downwardly from a bottom end of the body 40, are spaced apart from each other, and are positioned to two sides of the fastener cooperating hole 45 respectively, the fastener cooperating hole 45 is positioned in a depressed location of the body 40 which is concave shape and the fastener cooperating hole 45 specifically may be a screw hole. The body 40 of the supporting seat 4 has an inner face portion 40a which is toward an interior of the outer shell 2 (toward a direction that faces the end wall 23), an upper portion of the inner face portion 40a of the body 40 is constructed with the three fixing pins 42 and a lower portion of the inner face portion 40a of the body 40 is constructed with the supporting platform portion 41, the supporting platform portion 41 protrudes from the body 40 toward the interior of the outer shell 2 to form a boss-like structure, and the supporting platform portion 41 has a supporting top edge 411 and an inner face 412 which faces the interior of the outer shell 2. The fastener cooperating hole 45 allows a fastener 46 (see FIG. 2) to upwardly pass through a penetrating hole provided in the board 1 from a back face of the board 1 so as to be locked to the fastener cooperating hole 45, so that the supporting seat 4 is locked to the board 1 and bottom ends of the two erect brackets 43 are supported to the upper surface of the board 1, and when the supporting seat 4 is assembled to the end wall 23, an upper half portion of the body 40 abuts against a surface of the bulging portion 212 of the supporting seat fixing portion 21, the fixing pin 42 passes through the body 40 and the pin hole 211, and an end of the fixing pin 42 positioned to the recessed portion 213 forms a mushroom-like head 421 to be riveted to the recessed portion 213, so that the supporting seat 4 is engaged with and fixed to the supporting seat fixing portion 21, and the erect bracket 43 is supported on the surface of the board 1, the supporting top edge 411 is positioned below the bottom edge 25 to allow the bottom edge 25 to abut thereagainst, the supporting top edge 411 of the supporting platform portion 41 of each supporting seat 4 supports the bottom edge 25 of the lower end of the supporting seat fixing portion 21 relative to a downward direction to attain a supporting function, therefore, besides that the supporting platform portion 41 supports the bottom edge 25 of the supporting seat fixing portion 21, at the same time the supporting seat 4 is also riveted to the supporting seat fixing portion 21 by means of the fixing pin 42.

In the present embodiment, as shown in FIG. 9, positions of the plurality of supporting seats 4 provided on the two end walls 23 are that, the two adjacent supporting seat 4 on each end wall 23 are spaced apart from each other by a width distance of at least one supporting seat 4, and, the supporting seats 4 on one of the two end walls 23 and the supporting seats 4 on the other of the two end walls 23 are staggered by a width distance of at least one supporting seat 4 in the transverse direction W, such a configuration may use a relationship that the supporting seats 4 on the two end walls 23 are different in positions and are spaced apart from each other by a sufficient distance, to more stably support the outer shell 2 on the board 1. In addition, in the present embodiment, when the supporting seat 4 is engaged with and fixed to the supporting seat fixing portion 21, the mushroom-like head 421 of the fixing pin 42 positioned in the recessed portion 213 is not beyond the inner surface of the end wall 23, and the inner face 412 of the supporting platform portion 41 also is not beyond the inner surface of the end wall 23, which thus may prevent affecting that the pluggable module 3a inserts into the inserting passageway 20.

A material of the supporting seat 4 may be a plastic which does not have electrical conductivity, or a metal which has electrical conductivity or a material that a plastic covered with a metal to make the material have electrical conductive effect, at this time, by that the erect bracket 43 contacts a ground pad provided to the board 1, ground and electromagnetic shielding effect of the guiding shield cage 2a also may be increased.

Therefore, it can be seen from the content described as above, in the present disclosure, by provision of the supporting seat fixing portion 21 and the supporting seat 4, it may attain to strengthen retention force of the outer shell 2 and resistance of the outer shell 2 to insertion force in structure, and the supporting seat 4 also does not affect that the pluggable module 3a inserts into the inserting passageway 20, so the object of the present disclosure can be indeed attained.

In addition, by formation of the air flow through hole 11 of the board 1 and the inserting passageway 20 communicated with the air flow through hole 11, heat dissipating effect of the outer shell 2 is efficiently promoted, furthermore, using the air flow passageways 51, 61 of the longitudinal partitioning component 5 and the transverse partitioning component 6, and the air flow passageways 51, 61 both are formed with the front end openings 50a, 60a and the bottom end openings 50b, 60b, and provision of the air flow holes 531 of the front end plate 53 of the longitudinal partitioning component 5 and the bottom end air flowing gaps 525, 64, it allows air flow to flow through the longitudinal partitioning component 5 and the transverse partitioning component 6, it also make the longitudinal partitioning component 5 and the transverse partitioning component 6 have heat dissipating effect.

However, the above description is only for the embodiments of the present disclosure, and it is not intended to limit the implementing scope of the present disclosure, and the simple equivalent changes and modifications made according to the claims and the contents of the specification are still included in the scope of the present disclosure.

What is claimed is:

1. A connector assembly, comprising:
a guiding shield cage comprising an outer shell and a plurality of supporting seat fixing portions which are formed to a bottom end of the outer shell, each supporting seat fixing portion comprising a first engaging portion and a first supporting portion; and
a plurality of supporting seats respectively assembled to the plurality of supporting seat fixing portions, each supporting seat comprising a second engaging portion and a second supporting portion; the second engaging portion and the first engaging portion being engaged with and fixed to each other, the second supporting portion supporting the first supporting portion relative to a direction that the outer shell is toward the down.

2. The connector assembly of claim 1, wherein
each supporting seat fixing portion comprises a bulging portion which bulges outwardly from an outer surface of the outer shell and a recessed portion which is recessed from an inner surface of the outer shell.

3. The connector assembly of claim 2, wherein
the first engaging portion comprises a plurality of pin holes which penetrate the supporting seat fixing portion, the first supporting portion comprises a bottom edge of a lower end of the supporting seat fixing portion;
the second supporting portion of each supporting seat comprises a supporting platform portion, the second engaging portion comprises a plurality of fixing pins;
the plurality of fixing pins are respectively engaged to the plurality of pin holes of the supporting seat fixing portion, the supporting platform portion extends inwardly relative to the outer shell and supports the bottom edge of the lower end of the supporting seat fixing portion.

4. The connector assembly of claim 3, wherein
each supporting seat fixing portion further comprises a bottom cutout, the bottom edge of each supporting seat fixing portion and a bottom edge of the outer shell therebetween form the bottom cutout which is recessed upwardly,
the supporting platform portion extends inwardly into the bottom cutout relative to the outer shell and supports the bottom edge of the lower end of the supporting seat fixing portion.

5. The connector assembly of claim 3, wherein
each supporting platform portion has an inner face which faces an interior of the outer shell, the inner face of the supporting platform portion is not beyond the inner surface of the outer shell, one ends of the plurality of fixing pins positioned in the outer shell are not beyond the inner surface of the outer shell.

6. The connector assembly of claim 5, wherein
the connector assembly further comprises a board,
each supporting seat further comprises a body, a fastener cooperating hole which is positioned to the body and erect brackets which are positioned to a bottom end of the body, the fastener cooperating hole allows a fastener to pass through so as to lock the supporting seat to the board, the erect brackets are supported to a surface of the board.

7. The connector assembly of claim 6, wherein
the fastener cooperating hole is a screw hole, and
the board is provided with a penetrating hole which allows the fastener to upwardly pass through the penetrating hole from the board and be locked to the fastener cooperating hole.

8. The connector assembly of claim 1, wherein
the outer shell comprises two end walls which face each other in a longitudinal direction and two side walls which face each other in a transverse direction,
the plurality of supporting seats are provided to the two end walls, and the two adjacent supporting seats on each end wall are spaced apart from each other by a width distance of at least one supporting seat, the supporting seats of one of the two end walls and the supporting seats of the other of the two end walls are staggered by a width distance of at least one supporting seat in the transverse direction.

9. The connector assembly of claim 3, wherein
an end of each fixing pin positioned in the recessed portion forms a mushroom-like head to be riveted to the recessed portion.

10. The connector assembly of claim 1, wherein
the connector assembly further comprises a board,
the guiding shield cage is uprightly assembled to the board to extend up and down toward a height direction, and
the guiding shield cage further comprises a longitudinal partitioning component and transverse partitioning components, the longitudinal partitioning component and the transverse partitioning components partition an internal space of the outer shell into a plurality of inserting passageways, each inserting passageway has a front inserting opening which is away from the board and a bottom opening which is adjacent to the board.

11. A connector assembly, allowing a pluggable module to insert therein, the connector assembly comprising:
a board formed with a plurality of air flow through holes; and
a guiding shield cage provided to the board and comprising:
an outer shell comprising two end walls which face each other in a longitudinal direction and two side walls which face each other in a transverse direction;
a longitudinal partitioning component extending along the longitudinal direction, assembled to the two end walls, and comprising two longitudinal partitioning plates which are spaced apart from each other and an air flow passageway which is formed between the two longitudinal partitioning plates and is communicated with the plurality of air flow through holes; and
transverse partitioning components each comprising two transverse partitioning plates which are spaced apart from each other and an air flow passageway which is formed between the two transverse partitioning plates and is communicated with the air flow through hole, the transverse partitioning component extending along transverse direction and being assembled on the longitudinal partitioning component and one of the two side walls of the outer shell, so that an internal space of the outer shell being partitioned into a plurality of inserting passageways, each inserting passageway extending along an inserting direction of the pluggable module and having a front inserting opening which is away from the board and a bottom opening which is adjacent to the board.

12. The connector assembly of claim 11, wherein
the longitudinal partitioning component and the board therebetween form a bottom end air flowing gap;
the transverse partitioning component and the board therebetween form a bottom end air flowing gap.

13. The connector assembly of claim 12, wherein
a bottom end of the longitudinal partitioning component is provided with raising protrusions, is raised over the board by the raising protrusions, the longitudinal partitioning component and the board therebetween form the bottom end air flowing gap.

14. The connector assembly of claim 12, wherein
a bottom end of the outer shell and the board therebetween form bottom end air flowing gaps.

15. The connector assembly of claim 14, wherein
the bottom end of the outer shell has retaining legs and raising protrusions, the retaining legs are used to be fixed to the board, are raised over the board by the raising protrusions, the outer shell and an upper surface of the board therebetween form the bottom end air flowing gaps.

16. The connector assembly of claim 11, wherein
the longitudinal partitioning component comprises a pair of longitudinal partitioning plates which are spaced apart from each other and a front end plate which extends along the longitudinal direction from between front ends of the two longitudinal partitioning plates,
the two longitudinal partitioning plates therebetween define the air flow passageway, the front end plate has a plurality of air flow holes which cover most of a front end opening of the air flow passageway.

17. The connector assembly of claim 16, wherein
the longitudinal partitioning component further comprises a bottom supporting piece which is interposed between the two longitudinal partitioning plates, the bottom supporting piece is partially positioned to a bottom end opening of the air flow passageway.

18. The connector assembly of claim 17, wherein
the bottom supporting piece bends and extends from a bottom edge of one of the two longitudinal partitioning plates toward the other of the two longitudinal partitioning plates and has a protruding piece used to snap to an inserting hole which is provided to the other of the two longitudinal partitioning plates.

19. The connector assembly of claim 16, wherein
the front end plate extends from a front end edge of one of the two longitudinal partitioning plates toward the other of the two longitudinal partitioning plates (52), and the front end plate has a protruding piece which is used to snap to the other of the two longitudinal partitioning plates.

20. The connector assembly of claim 11, wherein
the transverse partitioning component comprises a pair of transverse partitioning plates which are spaced apart from each other, the two transverse partitioning plates therebetween define the air flow passageway, each transverse partitioning plate has a bendable piece which is positioned to a front end of the transverse partitioning plate and is locally positioned in a front end opening of the air flow passageway, positions of the two bendable pieces of the two transverse partitioning plates are staggered with each other along the transverse direction, the two bendable piece s are locally positioned in the front end opening of the air flow passageway.

21. The connector assembly of claim 20, wherein
the transverse partitioning component further comprises side supporting pieces which are interposed between the two transverse partitioning plates, the two transverse partitioning plates are therebetween provided with internal supporting pieces.

22. The connector assembly of claim 21, wherein
some of the side supporting pieces and the two transverse partitioning plates are integrally connected.
